(19) United States
(12) Patent Application Publication
(10) Pub. No.: US 2020/0196444 A1
(43) Pub. Date: Jun. 18, 2020

(54) PRINTED CIRCUIT BOARD

(71) Applicant: SAMSUNG ELECTRO-MECHANICS CO., LTD., Suwon-si (KR)

(72) Inventors: Ju-Ho JIN, Suwon-si (KR); Hee-Ju KIM, Suwon-si (KR); Mun-Young SHIM, Suwon-si (KR); Won-Young JANG, Suwon-si (KR)

(73) Assignee: SAMSUNG ELECTRO-MECHANICS CO., LTD., Suwon-si (KR)

(21) Appl. No.: 16/546,676

(22) Filed: Aug. 21, 2019

(30) Foreign Application Priority Data
Dec. 12, 2018 (KR) 10-2018-0160120
Jan. 24, 2019 (KR) 10-2019-0009116

(51) Int. Cl. H05K 1/11

(52) U.S. Cl. CPC H05K 1/113; H05K 3/429; H05K 2201/09827; H05K 2201/09627

(57) ABSTRACT

A printed circuit board including: a circuit layer including a plurality of circuit layers; a first structure including a plurality of first unit vias, each first unit via being vertically disposed and formed between successive circuit layers that are vertically adjacent to each other; and a second structure including a plurality of second unit vias, each second unit via being vertically disposed and horizontally spaced apart from a respective first unit via, wherein a horizontal spaced distance between each respective first unit via and the second unit via is a set value or less.

### CROSS-REFERENCE TO RELATED APPLICATION

This application claims the benefit under 35 USC 119(a) of Korean Patent Application No. 10-2018-0160120, filed on Dec. 12, 2018, and Korean Patent Application No. 10-2019-0009116, filed on Jan. 24, 2019, the entire disclosures of which are hereby incorporated by reference for all purposes.

### BACKGROUND

### 1. Technical Field

The following description relates to a printed circuit board.

### 2. Description of the Background

A higher function and slimness of electronic devices such as smart phones are continuously developed, and electronic components mounted on the electronic devices are also increasingly densified. Accordingly, circuits of a printed circuit board (PCB) on which the electronic components are mounted may be designed to have fine widths and fine pitches.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes: a circuit layer including a plurality of circuit layers; a first structure including a plurality of first unit vias, each first unit via being vertically disposed and formed between successive circuit layers that are vertically adjacent to each other; and a second structure including a plurality of second unit vias, each second unit via being vertically disposed and horizontally spaced apart from a respective first unit via. A horizontal spaced distance between each respective first unit via and the second unit via is a set value or less.

The first structure may include a first pad connected to the circuit layers and vertically connected to each of the first unit vias, and the second structure may include a second pad vertically connected to each of the second unit vias. The first pad and the second pad may be electrically insulated from each other, and at least a portion of the second pad may be in contact with the first pad.

The set value may be 1 mm. Each second unit via may be the only via disposed within the horizontal spaced distance from the respective first unit via. The number of the second structures may be plural.

In another general aspect, a printed circuit board includes: a plurality of circuit layers; and a via structure electrically connected to the circuit layers. The via structure includes: a plurality of unit vias, each of which is vertically disposed between successive circuit layers that are vertically adjacent to each other; and a via conductor formed around any one of the plurality of unit vias. A horizontal spaced distance between one unit via and the via conductor is a set value or less.

The via structure may further include a first pad connected to the circuit layer and vertically connected to each of the unit vias. The via conductor may be in contact with the first pad. The via conductor may be vertically connected to a second pad, and the second pad may be insulated from the first pad.

The set value may be 1 mm. The via conductor may be the only via disposed within the horizontal spaced distance from one unit via. The number of the via conductors may be plural.

Other features and aspects will be apparent from the following detailed description, the drawings, and the claims.

### BRIEF DESCRIPTION OF THE DRAWINGS

FIG. 1 is a view illustrating a via structure and a printed circuit board including the same.

FIGS. 2 and 3 are views illustrating a via structure and a printed circuit board including the same according to an example.

FIGS. 4 and 5 are views illustrating a via structure and a printed circuit board including the same according to an example.

FIGS. 6 and 7 are views illustrating a via structure and a printed circuit board including the same according to an example.

FIGS. 8 and 9 are views illustrating a via structure and a printed circuit board including the same according to an example.

FIGS. 10 and 11 are views illustrating a via structure and a printed circuit board including the same according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

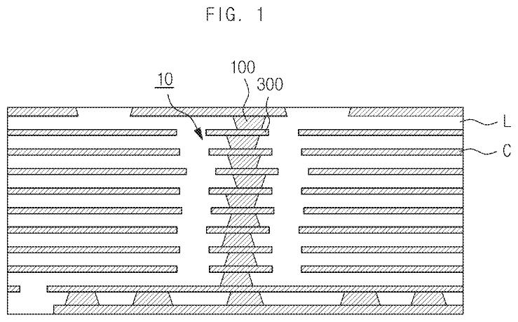

FIG. 1 is a view illustrating a via structure and a printed circuit board including the same.

Referring to FIG. 1, a printed circuit board may include a plurality of insulating layers L and a via structure 10. The via structure 10 may be a ‘stack via structure’ in which unit vias 100 formed on the plurality of insulating layers L, respectively, and vertically connected to each other are vertically stacked.

Each of the unit vias 100 may have the same shape. For example, each of the unit vias 100 has a cross sectional area that becomes smaller toward a lower side thereof, and may have an inverted trapezoid in a longitudinal section.

Alternatively, any one of the plurality of unit vias 100 may have a cross sectional area (e.g., an invert trapezoidal longitudinal section) that becomes smaller toward a lower side thereof, and the other unit via may have a cross sectional area (e.g., a normal trapezoidal longitudinal section) that becomes larger toward a lower side thereof. In this case, the unit vias 100 positioned on an upper side and the unit vias 100 positioned on a lower side with respect to a central layer (e.g., a core layer) of the printed circuit board may have a shape symmetrical to each other. That is, each of the unit vias 100 positioned on the upper side with respect to the central layer may have a cross-sectional area that becomes smaller toward the lower side thereof, and each of the unit vias 100 positioned on the lower side with respect to the central layer may have a cross-sectional area that becomes larger toward the lower side thereof.

The cross section of each of the unit vias 100 may be a circular shape.

The plurality of unit vias 100 may be vertically stacked so as to have the same center line. However, since the same center line means a center line placed at the same position within an error range, the unit vias 100 may be completely vertically stacked, or may be stacked with a slight offset in a vertical direction.

The unit vias 100 may be stacked while having a first pad 300 interposed therebetween. In this case, the first pad 300 is formed on at least one surface of each of the unit vias 100, such that a repeated structure of “pad-unit via-pad-unit via-pad” may be implemented. The first pad 300 may be connected to a circuit layer C formed on the insulating layer L. Accordingly, the unit vias 100 may perform an interlayer signal connection.

Each of the unit vias 100 may be formed by processing a via hole in the insulating layer L and then performing a metal-plating in the via hole. Here, when uniformity of the metal plating and uniformity of a size of the via hole are high in the entirety of the via structure 10, reliability of the via structure 10 may be increased. For example, in the via structure 10 including the unit vias 100 which are vertically stacked, when a contraction phenomenon occurs in one unit via, a crack may occur in the above-mentioned unit via, and as a result, the reliability of the via structure 10 may be weakened. Therefore, in order to secure the reliability of the via structure 10, the via structure 10 capable of preventing the contraction phenomenon or supplementing the contraction phenomenon is required.

Specific examples will hereinafter be described.

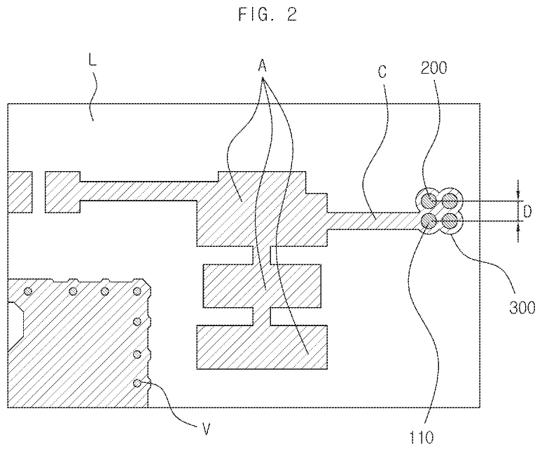

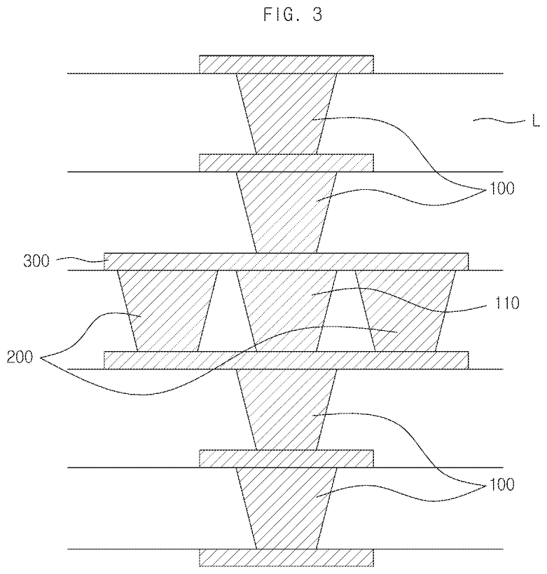

FIGS. 2 and 3 are views illustrating a via structure and a printed circuit board including the same according to a first example.

Referring to FIGS. 2 and 3, a via structure includes a plurality of unit vias 100 and 110 which are vertically disposed, and via conductors 200 may be formed in the vicinity of one of the plurality of unit vias 100 and 110 so as to be spaced apart from one unit via by a predetermined interval or less. That is, a horizontal spaced distance between one unit via 110 and the via conductor 200 may be a set value or less.

The unit vias 100 and 110 may be vertically disposed. The plurality of unit vias 100 and 110 may be vertically stacked so as to have the same center line. However, since the same center line means a center line placed at the same position within an error range, the unit vias 100 and 110 may be completely vertically stacked, or may be stacked with a slight offset in a vertical direction.

The unit vias 100 may be stacked to be vertically connected to each other while having a first pad 300 interposed therebetween. The first pad 300 may be electrically connected to the via conductors 200. The first pad 300 may be connected to a circuit layer C, and accordingly, the unit vias 100 and 110 and the via conductors 200 may perform an interlayer signal connection.

Each of the unit vias 100 and 110 may be formed by forming a via hole and then performing a metal-plating in the via hole. The via conductors 200 may also be provided by forming via holes and then forming metal-plating layers in the via holes.

The via conductors 200 may be spaced apart from one unit via 110 by the set value or less in a horizontal direction. One unit via 110 may be formed to be contracted when the via conductors are omitted in the via structure. That is, when it is expected that the contraction phenomenon occurs in one unit via 110, the via structure may be implemented to include the via conductors 200 in the vicinity of the unit via 110. Here, “being formed to be contracted” may mean that the via hole of the unit via 110 is formed to be smaller than a design.

A method for specifying the unit via 110 expected to cause the contraction phenomenon is as follows. First, the via structure is implemented so as not to include the via conductors 200 described above, and the presence or absence of a via crack in each of the unit vias is checked. In the case in which the via crack occurs, in particular, in the case in which the number of unit vias in which the via crack occurs is plural, a positional common to the plurality of unit vias in which the via cracks occur, and a via crack occurrence mechanism (whether or not a contraction phenomenon occurs) are found. Therefore, it is possible to specify a position of the unit via in which the via crack may occur.

For example, in a case in which the unit via is isolated so as to be horizontally spaced apart from other vias (vias other than the via structure) (V in FIG. 2) within the same layer by a certain numerical value or more, it may be determined that the crack may occur in the isolated unit via, and the certain numerical value may be 1 mm. Such a certain numerical value may be referred to as the “set value” described above.

Thereby, in the case in which the unit via is formed so as to be spaced apart from other vias in the same layer by 1 mm or more, the via conductors 200 may be formed around the unit via so as to be able to cope with the contraction phenomenon and the crack of the unit via.

As a specific example, in a laser facility for forming a via hole, a laser irradiation unit irradiates laser while moving in correspondence with a predetermined position. Here, when a movement distance is larger than the set value, an energy provided by the laser may be reduced. That is, in a case in which the laser facility processes a via hole of a unit via that is too far apart, the corresponding via hole may be processed to be smaller than a design. Therefore, the energy provided by the laser may be secured by first processing the via hole of the via conductor before processing the via hole of the unit via that is too far apart, and then shortly moving the laser irradiation unit to process the via hole of the unit via.

An interval (pitch) between the unit via 110 and the via conductor 200 may be 1 mm or less. For example, as illustrated in FIG. 2, the cross section of each of the unit vias 110 and the via conductors 200 may be a circular shape, and a distance D between centers of the unit via 110 and the via conductor 200 may be 1 mm or less.

The unit vias 110 and the via conductors 200 may be variously disposed. The unit vias 110 and the via conductors 200 may be disposed to have a plurality of rows and a plurality of columns such as a 2×2 structure as illustrated in FIG. 2, and may be disposed in series such as a 1×3 structure as illustrated in FIG. 3.

A size of the via conductor 200 may be equal to a size of the unit via 110, but may be different from the size of the unit via 110 and is not limited thereto.

In the present example, the via conductors 200 serve to transfer the signals. In this case, as illustrated in FIG. 3, the unit via 110 is in contact with the first pad 300, such that the unit via 110 and the via conductor 200 may share the same first pad 300. The shared first pad 300 may be connected to the circuit layer C. When the number of the via conductors 200 is plural, all of the via conductors 200 may be connected to the first pad 300 of the unit via 110.

According to such a via structure, even though the contraction phenomenon or the crack occurs in the unit via 110 positioned in any one layer, the signal transfer path is increased by the via conductor 200, which may supplement the signal transfer function. As a result, reliability of the entire via structure may be further secured.

The printed circuit board according to the first example includes the plurality of insulating layers L and the via structure. The insulating layers L are vertically stacked and the via structure is formed in the plurality of insulating layers L. The via structure may be formed throughout the plurality of insulating layers L, and may be electrically connected to the circuit layer C formed on each of the plurality of insulating layers L.

The via structure may include the unit vias 100 and 110 which are vertically disposed, and each of the unit vias 100 and 110 may be formed to penetrate through one of the plurality of insulating layers L. Each of the unit vias 100 and 110 may include a via hole formed in the insulating layer L, and a plating layer formed in the via hole.

The via conductor 200 spaced apart from the unit via 110 may be formed on at least one layer of the plurality of insulating layers L. The unit via 110 and the via conductor 200 may penetrate through the same insulating layer L, and may be horizontally spaced apart from each other in the corresponding insulating layer L by a set value or less. The via conductor 200 may include a via hole formed in the insulating layer L, and a plating layer formed in the via hole.

As described above, the via hole of the via conductor 200 is processed before the via hole of the unit via 110, so that the size of the via hole of the unit via 110 may be secured. The via conductor 200 may perform an interlayer signal transfer.

The insulating layer L may be formed of an organic material or an inorganic material, and may be formed of a material containing a resin. The resin forming the insulating layer L may include at least one of a thermosetting resin and a thermoplastic resin. As the thermosetting resin, an epoxy resin or the like may be used, and as the thermoplastic resin, polyimide, liquid crystal polymer, and the like may be used.

The circuit layer C may provide a path for transferring electrical signals and may be formed in each of the insulating layers L. The circuit layer C may be formed of copper (Cu), silver (Ag), platinum (Pt), aluminum (Al), palladium (Pd), or a metal thereof.

The printed circuit board according to the first example may be an antenna substrate. In this case, a part of the circuit layer C may serve as an antenna. Here, as illustrated in FIG. 2, the part serving as the antenna may be a plurality of patch antennas (antenna array) A.

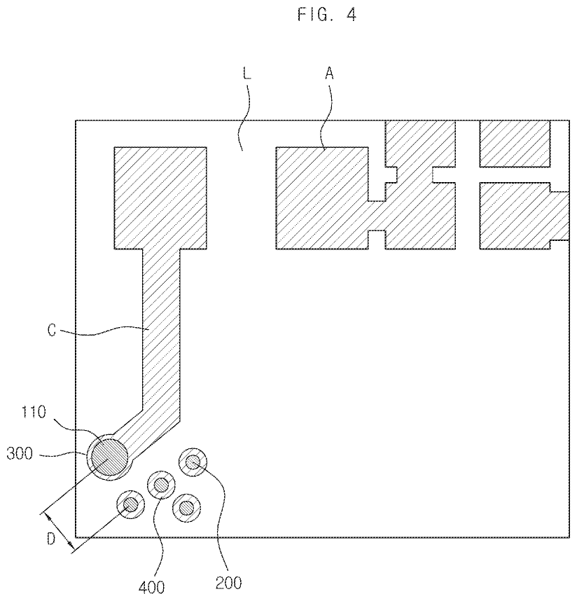

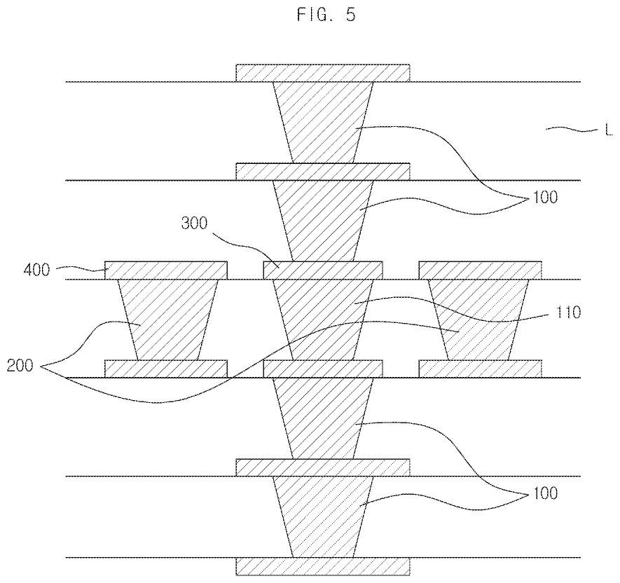

FIGS. 4 and 5 are views illustrating a via structure and a printed circuit board including the same according to a second example.

Referring to FIGS. 4 and 5, a via structure includes a plurality of unit vias 100 and 110 which are vertically disposed, and via conductors 200 may be formed in the vicinity of one of the plurality of unit vias 100 and 110 so as to be spaced apart from one unit via by a predetermined interval or less. That is, a horizontal spaced distance between one unit via 110 and the via conductor 200 may be a set value or less.

The unit vias 100 and 110 may be vertically disposed. The plurality of unit vias 100 and 110 may be vertically stacked so as to have the same center line. However, since the same center line means a center line placed at the same position within an error range, the unit vias 100 and 110 may be completely vertically stacked, or may be stacked with a slight offset in a vertical direction.

The unit vias 100 and 110 may be stacked to be vertically connected to each other while having a first pad 300 interposed therebetween. The first pad 300 may be electrically insulated from the via conductors 200. The first pad 300 may be connected to a circuit layer C, and accordingly, the unit vias 100 and 110 may perform an interlayer signal connection. On the other hand, the via conductors 200 may be dummy vias that do not perform the signal transfer.

Referring to FIG. 5, the first pad 300 connected to the unit via 110 is connected to the unit via 100 of another layer but may not be connected to the via conductors 200. The via conductors 200 may have separate second pads 400, but the first pad 300 of the unit via 110 and the second pads 400 of the via conductors 200 may be electrically isolated from each other. The first pad 300 may be connected to the circuit layer C, and the second pads 400 of the via conductors 200 may not be connected to the circuit layer C.

Each of the unit vias 100 and 110 may be formed by forming a via hole and then performing a metal-plating in the via hole. The via conductors 200 may also be provided by forming via holes and then forming a metal-plating layer in the via holes.

The via conductors 200 may be spaced apart from one unit via 110 by the set value or less in a horizontal direction. One unit via 110 may be formed to be contracted when the via conductors are omitted in the via structure. That is, when it is expected that the contraction phenomenon occurs in one unit via 110, the via structure may be implemented to include the via conductors 200 in the vicinity of the unit via 110.

As a specific example, in a laser facility for forming a via hole, a laser irradiation unit irradiates laser while moving in correspondence with a predetermined position. Here, when a movement distance is larger than the set value, an energy provided by the laser may be reduced. That is, in a case in which the laser facility processes a via hole of a unit via that is too far apart, the corresponding via hole may be processed to be smaller than a design. Therefore, the energy provided by the laser may be secured by first processing the via hole of the via conductor before processing the via hole of the unit via that is too far apart, and then shortly moving the laser irradiation unit to process the via hole of the unit via.

That is, even though the via conductors 200 are the dummy vias that do not serve to transfer the signals, the via hole of the unit via 110 may be processed to a sufficient size by simply first processing the via holes of the via conductors 200.

An interval (pitch) between the unit via 110 and the via conductor 200 may be 1 mm or less. For example, as illustrated in FIG. 4, the cross section of each of the unit vias 110 and the via conductors 200 may be a circular shape, and a distance D between centers of the unit via 110 and the via conductor 200 may be 1 mm or less.

The unit vias 110 and the via conductors 200 may be variously disposed. As illustrated in FIG. 4, the number of the via conductors 200 is plural, and the plurality of via conductors 200 may be disposed to surround the unit via 100, and the circuit layer C connected to the unit via 110.

A size of the via conductor 200 may be equal to a size of the unit via 110, but may be different from the size of the unit via 110 and is not limited thereto. For example, the size of the via conductor 200 may be smaller than that of the unit via 110.

The printed circuit board according to the second example includes the plurality of insulating layers L and the via structure. The insulating layers L are vertically stacked and the via structure is formed in the plurality of insulating layers L. The via structure may be formed throughout the plurality of insulating layers L, and may be connected to the circuit layer C formed on each of the plurality of insulating layers L.

The via structure may include the unit vias 100 and 110 which are vertically disposed, and each of the unit vias 100 and 110 may be formed to penetrate through one of the plurality of insulating layers L. Each of the unit vias 100 and 110 may include a via hole formed in the insulating layer L, and a plating layer formed in the via hole.

The via conductor 200 spaced apart from the unit via 110 may be formed on at least one layer of the plurality of insulating layers L. The unit via 110 and the via conductor 200 may penetrate through the same insulating layer L, and may be horizontally spaced apart from each other in the corresponding insulating layer L by a set value or less. The via conductor 200 may include a via hole formed in the insulating layer L, and a plating layer formed in the via hole.

As described above, the via hole of the via conductor 200 is processed before the via hole of the unit via 110, so that the size of the via hole of the unit via 110 may be secured. Meanwhile, in the present exemplary embodiment, the via conductors 200 may be dummy vias that do not perform an interlayer signal transfer.

The insulating layer L may be formed of an organic material or an inorganic material, and may be formed of a material containing a resin. The resin forming the insulating layer L may include at least one of a thermosetting resin and a thermoplastic resin. As the thermosetting resin, an epoxy resin or the like may be used, and as the thermoplastic resin, polyimide, liquid crystal polymer, and the like may be used.

The circuit layer C may provide a path for transferring electrical signals and may be formed in each of the insulating layers L. The circuit layer C may be formed of copper (Cu), silver (Ag), platinum (Pt), aluminum (Al), palladium (Pd), or a metal thereof.

The printed circuit board according to the second example may be an antenna substrate. In this case, a part of the circuit layer C may serve as an antenna. Here, as illustrated in FIG. 4, the part serving as the antenna may be a plurality of patch antennas (antenna array) A.

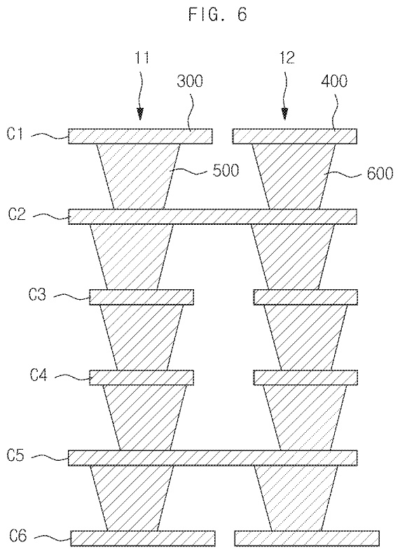

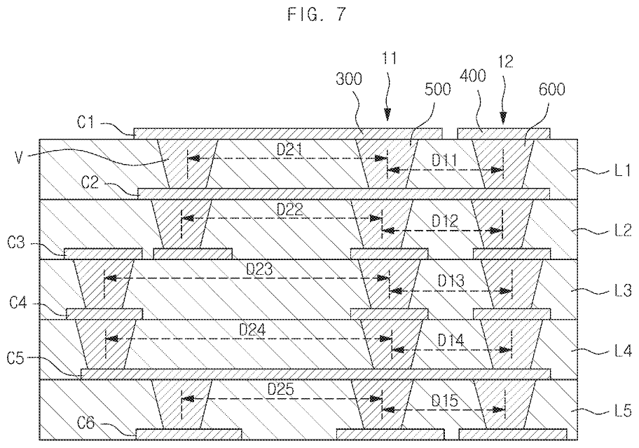

FIGS. 6 and 7 are views illustrating a via structure and a printed circuit board including the same according to a third example.

Referring to FIG. 6, a via structure may include a first structure 11 and a second structure 12.

The first structure 11 may include a plurality of first unit vias 500. The plurality of first unit vias 500 are vertically connected to each other to form a stack via structure. In particular, the first structure 11 may form an entire layer stack via structure that vertically connects all of the layers of the printed circuit board to each other.

The first unit vias 500 may electrically connected to the circuit layers C (C1 through C6) of the printed circuit board, and may perform conduction between the circuit layers C. In particular, the first unit via 500 forming the entire layer stack via structure is each formed between neighboring circuit layers C to perform vertical conduction of the entire circuit layer C.

The plurality of first unit vias 500 may be vertically stacked so as to have the same center line. However, since the same center line means a center line placed at the same position within an error range, the first unit vias 500 may be completely vertically stacked, or may be stacked with a slight offset in a vertical direction.

Each of the first unit vias 500 may have the same shape. For example, each of the first unit vias 500 has a longitudinal section of a trapezoid or an inverted trapezoid. However, the shapes of the plurality of first unit vias 500 are not limited thereto, but may be different from each other.

The first structure 11 may further include a first pad 300. The first pad 300 may be vertically connected to the first unit vias 500, and the plurality of first unit vias 500 may be stacked while having the first pad 300 interposed therebetween. In this case, the first pad 300 is formed on one surface of each of the first unit vias 500, such that the first structure 11 may be implemented as a repeated structure of “pad-unit via-pad-unit via-pad”.

The second structure 12 may include a plurality of second unit vias 600. The plurality of second unit vias 600 are vertically connected to each other to form a stack via structure. In particular, the second structure 12 may form an entire layer stack via structure that vertically connects all of the layers of the printed circuit board to each other.

The plurality of second unit vias 600 may be vertically stacked so as to have the same center line. However, since the same center line means a center line placed at the same position within an error range, the second unit vias 600 may be completely vertically stacked, or may be stacked with a slight offset in a vertical direction.

The second unit vias 600 are formed to correspond to the first unit vias 500, respectively. The first unit via 500 and the second unit via 600 that correspond to each other in the same layer are horizontally spaced apart from each other. Here, a phrase “horizontally spaced apart from each other” means that side surfaces of the first unit via 500 and the second unit via 600 are not in contact with each other.

Each of the second unit vias 600 may have the same shape. For example, each of the second unit vias 600 has a longitudinal section of a trapezoid or an inverted trapezoid. However, the shapes of the plurality of second unit vias 600 are not limited thereto, but may be different from each other.

The second structure 12 may further include a second pad 400. The second pad 400 may be vertically connected to the second unit vias 600, and the plurality of second unit vias 600 may be stacked while having the second pad 400 interposed therebetween. In this case, the second pad 400 is formed on one surface of each of the second unit vias 600, such that the second structure 12 may be implemented as a repeated structure of “pad-unit via-pad-unit via-pad”.

The number of the second structures 12 may be plural. Each of the second structures 12 may be implemented as a stack via structure. The plurality of second structures 12 may be formed to surround the first structure 11.

A horizontal spaced distance between the first structure 11 and the second structure 12 may be a set value or less. In particular, each of the first unit vias 500 may be horizontally spaced apart from the second unit via 600 formed in the same layer, and the horizontal spaced distance therebetween may be the set value or less. In addition, even in the case in which the number of the second structures 12 is plural, a horizontal spaced distance from the first structure 11 to each of the second structures 12 may be the set value or less.

Here, the horizontal spaced distance may be referred to as a distance between center lines of the unit vias. In addition, the set value is a set value of a condition in which the via holes may be uniformly processed during processing of the via holes of the unit vias. For example, in a laser facility for processing the via holes, when the via holes are spaced apart from each other by a specific distance or more during processing of the plurality of via holes, the via holes may be uniformly processed. Here, the set value is the specific distance. Specifically, the set value may be 1 mm.

The first unit vias 500 and the second unit vias 600 may be formed in the same number. Referring to FIG. 6, the first unit vias 500 and the second unit vias 600 are formed in five, respectively, but this is merely illustrative. The horizontal spaced distance between the first unit via 500 and the second unit via 600 formed in the same layer is the above-mentioned set value or less. That is, in all five layers, the horizontal spaced distance between the first unit vias 500 and the second unit vias 600 corresponding to each other is the set value or less.

Within the distance horizontally spaced from the first unit vias 500 by the set value, there may be no vias other than the second unit vias 600. That is, the first unit vias 500 may be vias that are far away from other vias in the same layer, and within the distance horizontally spaced from the first unit vias 500 by the set value, only the second unit vias 600 may exist.

In manufacturing the via structures, at the time of processing the via holes, when the via holes of the first unit vias 500 and the second unit vias 600 of the same layer are processed, the via holes of the first unit vias 500 may be processed before processing the via holes of the second unit vias 600. In this case, even though the via holes which are post processed at the time of processing the via holes are processed to be contracted due to a limitation of the facility, the limitation of the facility may be supplemented by processing the via holes of the first unit vias 500 after processing the via holes of the second unit vias 600.

Referring to FIG. 6, portions of the first pad 300 and the second pad 400 may be in contact with each other. For example, as illustrated in FIG. 6, in six pairs of the first pads 300 and the second pads 400, two pairs of the first pads 300 and the second pads 400 may be in contact with each other. In addition, other pairs of the first pads 300 and the second pads 400 may be spaced apart from each other and may be insulated from each other.

Referring to FIG. 7, the printed circuit board may include a plurality of insulating layers L (L1 through L5), a plurality of circuit layers C (C1 through C6), and a via structure. The via structure may include a first structure 11 and a second structure 12.

The insulating layers L are vertically stacked, and insulate the circuit layers C positioned on different layers. The via structure is formed in the plurality of insulating layers L. The via structure may be formed throughout the plurality of insulating layers L, and may be electrically connected to the circuit layers C.

The insulating layer L may be formed of an organic material or an inorganic material, and may be formed of a material containing a resin. The resin forming the insulating layer L may include at least one of a thermosetting resin and a thermoplastic resin. As the thermosetting resin, an epoxy resin or the like may be used, and as the thermoplastic resin, polyimide, liquid crystal polymer, and the like may be used.

The circuit layer C may provide a path for transferring electrical signals and may be formed in each of the insulating layers L. The circuit layer C may be formed of copper (Cu), silver (Ag), platinum (Pt), aluminum (Al), palladium (Pd), or a metal thereof.

The circuit layers C may be formed of N layers, and the insulating layers L may be formed of N−1 layers. In FIG. 7, the circuit layers C are formed of six layers and the insulating layers L are formed of five layers, but the circuit layers C and the insulating layers L are not limited thereto.

The first structure 11 is electrically connected to the circuit layer C. The first structure 11 includes a plurality of first unit vias 500. The first unit vias 500 are each formed between the circuit layers C that are vertically adjacent to each other. That is, the first unit vias 500 connect all of the circuit layers C that are vertically adjacent to each other. The plurality of first unit vias 500 are vertically disposed to form a stack via structure. In particular, the first structure 11 may form an entire layer stack via structure that vertically connects all of the circuit layers C.

Since the first unit vias 500 are each formed between the circuit layers C that are vertically adjacent to each other, the number of the first unit vias 500 may be N−1 when the circuit layers C are formed of N layers. In FIG. 7, the circuit layers C are formed of six layers and the number of the first unit vias 500 is five, but the circuit layers C and the number of the first unit vias 500 are not limited thereto.

The plurality of first unit vias 500 may be vertically stacked so as to have the same center line. However, since the same center line means a center line placed at the same position within an error range, the first unit vias 500 may be completely vertically stacked, or may be stacked with a slight offset in a vertical direction.

Each of the first unit vias 500 may have the same shape. For example, each of the first unit vias 500 has a longitudinal section of a trapezoid or an inverted trapezoid. However, the shapes of the plurality of first unit vias 500 are not limited thereto, but may be different from each other.

The first structure 11 may further include a first pad 300. The first pad 300 may be vertically connected to the first unit vias 500, and the plurality of unit vias 500 may be stacked while having the first pad 300 interposed therebetween. In this case, the first pad 300 is formed on one surface of each of the first unit vias 500, such that the first structure 11 may be implemented as a repeated structure of “pad-unit via-pad-unit via-pad”.

The second structure 12 may include a plurality of second unit vias 600. The plurality of second unit vias 600 are vertically disposed to form a stack via structure. The second structure 12 may form an entire layer stack via structure that vertically connects all of the layers of the printed circuit board to each other.

The plurality of second unit vias 600 may be vertically stacked so as to have the same center line. However, since the same center line means a center line placed at the same position within an error range, the second unit vias 600 may be completely vertically stacked, or may be stacked with a slight offset in a vertical direction.

The second unit vias 600 are formed to correspond to the first unit vias 500, respectively. The first unit via 500 and the second unit via 600 that correspond to each other in the same layer are horizontally spaced apart from each other. Here, a phrase “horizontally spaced apart from each other” means that side surfaces of the first unit via 500 and the second unit via 600 are not in contact with each other.

Each of the second unit vias 600 may have the same shape. For example, each of the second unit vias 600 has a longitudinal section of a trapezoid or an inverted trapezoid. However, the shapes of the plurality of second unit vias 600 are not limited thereto, but may be different from each other.

The second structure 12 may further include a second pad 400. The second pad 400 may be vertically connected to the second unit vias 600, and the plurality of second unit vias 600 may be stacked while having the second pad 400 interposed therebetween. In this case, the second pad 400 is formed on one surface of each of the second unit vias 600, such that the second structure 12 may be implemented as a repeated structure of “pad-unit via-pad-unit via-pad”.

The number of the second structures 12 may be plural. Each of the second structures 12 may be implemented as a stack via structure. The plurality of second structures 12 may be disposed to surround the first structure 11.

A horizontal spaced distance between the first structure 11 and the second structure 12 may be a set value or less. In particular, the horizontal spaced distance between the first unit via 500 and the second unit via 600 formed in the same layer may be the set value or less. In addition, even in the case in which the number of the second structures 12 is plural, a horizontal spaced distance from the first structure 11 to each of the second structures 12 may be the set value or less.

Here, the horizontal spaced distance may be a distance between center lines of the unit vias. The set value is a set value of a condition in which the via holes may be uniformly processed during processing of the via holes of the unit vias. For example, in a laser facility for processing the via holes, when the via holes are spaced apart from each other by a specific distance or more during processing of the plurality of via holes, the via holes may be uniformly processed. Here, the set value is the specific distance. Specifically, the set value may be 1 mm.

The first unit vias 500 and the second unit vias 600 may be formed in the same number. Referring to FIG. 7, the first unit vias 500 and the second unit vias 600 are formed in five, respectively, but this is merely illustrative. The horizontal spaced distance between the first unit via 500 and the second unit via 600 formed in the same layer is the set value or less. That is, in all five layers, the horizontal spaced distance between the first unit vias 500 and the second unit vias 600 corresponding to each other is the set value or less.

In FIG. 7, a horizontal spaced distance D11 between the first unit via 500 penetrating through an insulating layer L1 to connect circuit layers C1 and C2 to each other and the second unit via 600 formed in the same layer is the set value or less. A horizontal spaced distance D12 between the first unit via 500 penetrating through an insulating layer L2 to connect circuit layers C2 and C3 to each other and the second unit via 600 formed in the same layer is the set value or less. The horizontal spaced distances D13, D14, and D15 calculated in the same manner are all the set value or less. However, the values of D11 to D15 may be different from each other.

Within the distance horizontally spaced from the first unit vias 500 by the set value, there may be no vias other than the second unit vias 600. That is, the first unit vias 500 may be vias that are far away from other vias V in the same layer, and within the distance horizontally spaced from the first unit vias 500 by the set value, only the second unit vias 600 may exist.

In FIG. 7, other vias V other than the first vias 500 may exist between the circuit layers C1 and C2, but a distance D21 between the first unit via 500 and the via may be greater than the above-mentioned set value (for example, distance D21 is greater than distance D11). Similarly, D22, D23, D24, and D25 are all greater than the set value.

In manufacturing the via structures, at the time of processing the via holes, when the via holes of the first unit vias 500 and the second unit vias 600 of the same layer are processed, the via holes of the first unit vias 500 may be processed before processing the via holes of the second unit vias 600. In this case, even though the via holes which are post processed at the time of processing the via holes are processed to be contracted due to a limitation of the facility, the limitation of the facility may be supplemented by processing the via holes of the first unit vias 500 after processing the via holes of the second unit vias 600.

In FIG. 7, a relationship between the via V, the first unit via 500, and the second unit via 600 existing between the circuit layers C1 and C2 will be described. A via hole of the second unit via 600 is processed immediately before a via hole of the first unit via 500 spaced apart from the via V by the set value or more is processed after a via hole of the via V is formed. After the via hole of the second unit via 600 is processed, the via hole of the first unit via 500 is processed. Therefore, the above-mentioned limitation of the facility may be supplemented. Such a description may be applied to all other layers including the layer between the circuit layers C2 and C3.

For example, if all of the first unit vias 500 of the first structure 11 are spaced apart from a general via V by the set value or more, the second structure 12 of the same number of second unit vias 600 as the first unit vias 500 is required. In the via hole process, as the via hole of the first unit via 500 is processed after the via hole of the second unit via 600 is processed in the same layer, an unnecessary contraction phenomenon of the first unit via 500 may be prevented, and reliability of the first structure 11 may be also secured.

Referring to FIG. 7, portions of the first pad 300 and the second pad 400 may be in contact with each other. For example, as illustrated in FIG. 6, in six pairs of the first pads 300 and the second pads 400, two pairs of the first pads 300 and the second pads 400 may be in contact with each other. Other pairs of the first pads 300 and the second pads 400 may be spaced apart from each other and may be insulated from each other.

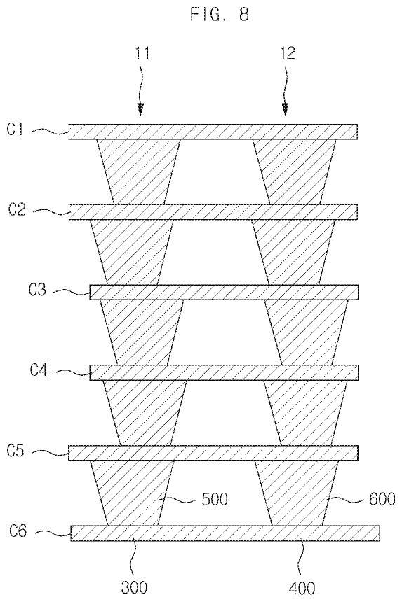

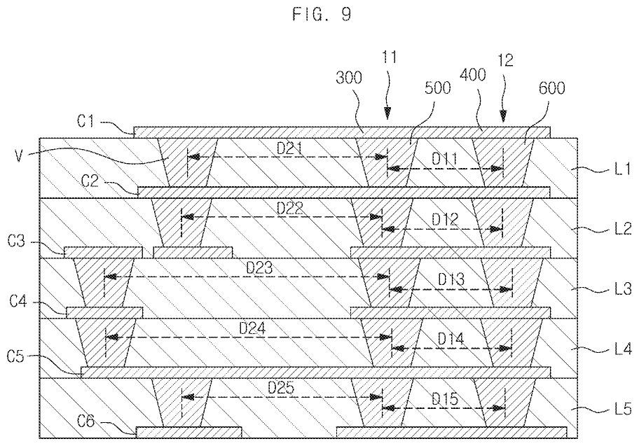

FIGS. 8 and 9 are views illustrating a via structure and a printed circuit board including the same according to a fourth example.

Referring to FIGS. 8 and 9, in a via structure and a printed circuit board including the same, all of the pairs of the first pads 300 and the second pads 400 are electrically connected to each other. That is, all of the pairs of first pads 300 and the second pads 400 are in contact with each other, and the first unit via 500 and the second unit via 600 share the connected pads.

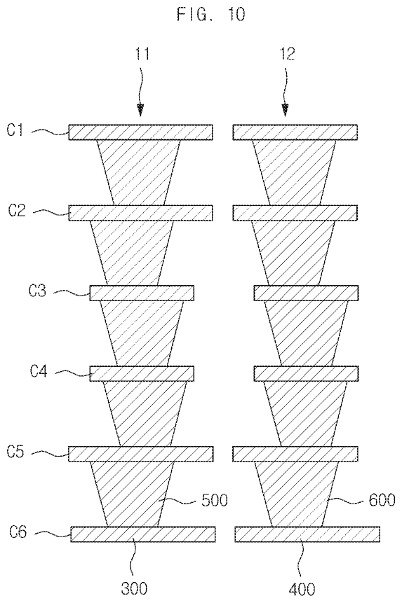

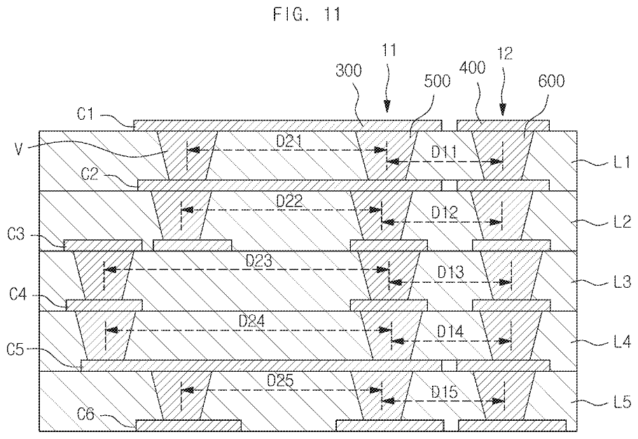

FIGS. 10 and 11 are views illustrating a via structure and a printed circuit board including the same according to a fifth example.

Referring to FIGS. 10 and 11, in a via structure and a printed circuit board including the same, all pairs of the first pads 300 and the second pads 400 are electrically insulated from each other. That is, all of the pairs of the first pads 300 and the second pads 400 are horizontally spaced apart from each other, and the second unit via 600 (second structure 12) is also insulated from the circuit layer C, does not participate in interlayer conduction of the circuit layer C, and exists as a dummy via.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a circuit layer comprising a plurality of circuit layers;
a first structure comprising a plurality of first unit vias, each first unit via being vertically disposed and formed between successive circuit layers that are vertically adjacent to each other; and
a second structure comprising a plurality of second unit vias, each second unit via being vertically disposed and horizontally spaced apart from a respective first unit via,
wherein a horizontal spaced distance between each respective first unit via and second unit via is a set value or less.

2. The printed circuit board of claim 1, wherein the first structure comprises a first pad connected to the circuit layers and vertically connected to each of the first unit vias.

3. The printed circuit board of claim 2, wherein the second structure comprises a second pad vertically connected to each of the second unit vias.

4. The printed circuit board of claim 3, wherein the first pad and the second pad are electrically insulated from each other.

5. The printed circuit board of claim 3, wherein at least a portion of the second pad is in contact with the first pad.

6. The printed circuit board of claim 1, wherein the set value is 1 mm.

7. The printed circuit board of claim 1, wherein each second unit via is the only via disposed within the horizontal spaced distance from the respective first unit via.

8. The printed circuit board of claim 1, further comprising a plurality of the second structures.

9. A printed circuit board comprising:
a plurality of circuit layers; and
a via structure electrically connected to the circuit layers,
wherein the via structure comprises:
a plurality of unit vias, each of which is vertically disposed between successive circuit layers that are vertically adjacent to each other; and
a via conductor formed around any one of the unit vias,
wherein a horizontal spaced distance between one unit via and the via conductor is a set value or less.

10. The printed circuit board of claim 9, wherein the via structure comprises a first pad connected to the circuit layers and vertically connected to each of the unit vias.

11. The printed circuit board of claim 10, wherein the via conductor is in contact with the first pad.

12. The printed circuit board of claim 10, wherein the via conductor is vertically connected to a second pad, and
the second pad is insulated from the first pad.

13. The printed circuit board of claim 9, wherein the set value is 1 mm.

14. The printed circuit board of claim 9, wherein the via conductor is the only via disposed within the horizontal spaced distance from one unit via.

15. The printed circuit board of claim 9, further comprising a plurality of the via conductors.
